(19) United States
(12) Patent Application Publication
(10) Pub. No.: US 2011/0220493 A1
(43) Pub. Date: Sep. 15, 2011

(54) MASKING MATERIAL, PIEZOELECTRIC VIBRATOR, METHOD OF MANUFACTURING PIEZOELECTRIC VIBRATOR, OSCILLATOR, ELECTRONIC APPARATUS, AND RADIO-CONTROLLED TIMEPIECE

(76) Inventor: Kiyoshi Aratake, Chiba-shi (JP)

(21) Appl. No.: 13/047,210

(22) Filed: Mar. 14, 2011

(30) Foreign Application Priority Data
Mar. 15, 2010 (JP) 2010-058423

(51) Int. Cl. C23C 14/34; H01L 41/22

(52) U.S. Cl. 204/298.11; 29/25.35

(57) ABSTRACT

Provided are a masking material capable of suppressing the occurrence of pattern blurring when forming a pattern on a substrate by a sputtering method, a piezoelectric vibrator using the masking material, a method of manufacturing the piezoelectric vibrator, and an oscillator, an electronic device, and a radio-controlled timepiece each having the piezoelectric vibrator. A masking material which is used when forming a pattern on a substrate by a sputtering method includes openings corresponding to the pattern, and portions where the openings are not formed have a uniform thickness.

### RELATED APPLICATIONS

This application claims priority under 35 U.S.C. §119 to Japanese Patent Application No. 2010-058423 filed on Mar. 15, 2010, the entire content of which is hereby incorporated by reference.

### BACKGROUND OF THE INVENTION

1. Field of the Invention

The present invention relates to a masking material which is used when forming an electrode pattern (pattern) of a surface mounted device (SMD)-type piezoelectric vibrator in which a piezoelectric vibrating reed is sealed in a cavity formed between two bonded substrates, a piezoelectric vibrator having the electrode pattern formed using the masking material, a method of manufacturing the piezoelectric vibrator, and an oscillator, an electronic apparatus, and a radio-controlled timepiece each having the piezoelectric vibrator.

2. Description of the Related Art

Recently, a piezoelectric vibrator utilizing quartz or the like has been used in cellular phones and portable information terminals as the time source, the timing source of a control signal, a reference signal source, and the like. Although there are various piezoelectric vibrators of this type, a surface mounted device-type piezoelectric vibrator is known as one example thereof. As a piezoelectric vibrator of this type, a piezoelectric vibrator which has a two-layered structure in which a base substrate and a lid substrate are directly bonded, and a piezoelectric vibrating reed is accommodated in a cavity formed between the two substrates is known. Moreover, a piezoelectric vibrator in which the piezoelectric vibrating reed is bump-bonded to an electrode pattern formed on a base substrate, for example, the piezoelectric vibrating reed is electrically connected to outer electrodes formed on the base substrate using a conductive member which is formed so as to penetrate through the base substrate is known (for example, see JP-A-10-32449 and JP-A-9-331228).

This piezoelectric vibrator 200 includes a base substrate 201 and a lid substrate 202 which are anodically bonded to each other by a bonding film 207 and a piezoelectric vibrating reed 203 which is sealed in a cavity C formed between the two substrates 201 and 202, as shown in FIGS. 30 and 31. The piezoelectric vibrating reed 203 is a tuning-fork type vibrating reed, for example, and is mounted on the upper surface of the base substrate 201 in the cavity C by a conductive adhesive E.

The base substrate 201 and the lid substrate 202 are insulating substrates, for example, made of ceramics, glass, and the like. Among the two substrates, a through-hole 204 is formed on the base substrate 201 so as to penetrate through the base substrate 201. Moreover, a conductive member 205 is buried in the through-hole 204 so as to block the through-hole 204. The conductive member 205 is electrically connected to outer electrodes 206 which are formed on the lower surface of the base substrate 201 and is connected to the piezoelectric vibrating reed 203 mounted in the cavity C through lead-out electrodes (electrode patterns) 236 and 237.

However, in the piezoelectric vibrator 200 of the related art, a sputtering method or the like is used as a method of forming the lead-out electrodes 236 and 237 on the base substrate 201. Specifically, as shown in FIG. 32, sputtering is performed in a state where a wafer 240 serving as the base substrate 201 is placed on a base plate 271, and a masking material 280 is placed so as to cover the base plate 271, whereby the lead-out electrodes 236 and 237 are formed on the surface of the wafer 240. On the masking material 280, openings 281 are formed so as to correspond to the pattern of the lead-out electrodes 236 and 237. Moreover, a peripheral portion 284 of the masking material 280 is thick so as to secure the strength of the masking material 280. For example, a thin region where the openings 281 are formed has a thickness of about several tens of and the peripheral portion 284 has a thickness of about several millimeters.

When sputtering is performed using the masking material 280 having such a configuration, particularly when the lead-out electrodes 236 and 237 are patterned on the wafer 240 such as glass having poor thermal conductivity, pattern blurring is likely to occur. This is because the thermal capacity in the vicinity of the openings 281 of the masking material 280 is different from that of the peripheral portion 284, the masking material 280 may be thermally expanded and bent. Particularly, when the size of the wafer 240 increases, the amount of bending increases further, and the pattern blurring also increases further.

### SUMMARY OF THE INVENTION

The present invention has been made in view of the above problems, and an object of the present invention is to provide a masking material capable of suppressing the occurrence of pattern blurring when forming a pattern on a substrate by a sputtering method, a piezoelectric vibrator using the masking material, a method of manufacturing the piezoelectric vibrator, and an oscillator, an electronic device, and a radio-controlled timepiece each having the piezoelectric vibrator.

The present invention provides the following means in order to solve the problems.

According to an aspect of the present invention, there is provided a masking material which is used when forming a pattern on a substrate by a sputtering method, the masking material including openings corresponding to the pattern, in which portions where the openings are not formed have a uniform thickness.

According to the masking material of the above aspect of the present invention, since the thickness of the masking material is uniform except for the regions of the openings, even when the temperature of the masking material increases during the sputtering, there is no difference in the amount of thermal expansion in the masking material. Thus, it is possible to prevent the occurrence of bending of the masking material. Accordingly, it is possible to suppress the occurrence of pattern blurring when the pattern is formed on the substrate by the sputtering method.

According to another aspect of the present invention, there is provided a masking material which is used when forming a pattern on a substrate that is configured to form a plurality of fragments by a sputtering method, the masking material including openings corresponding to the pattern, in which portions corresponding to boundary portions of the adjacent fragments have approximately the same thicknesses as the thickness of a peripheral portion of the substrate.

According to the masking material of the above aspect of the present invention, since the thickness of the peripheral portion of the substrate is the same as the thicknesses of the boundary portions, approximately the entire region of the masking material has the same thickness as the peripheral portion. That is, it is possible to prevent the occurrence of bending of the masking material resulting from the difference in the amount of thermal expansion. Accordingly, it is possible to suppress the occurrence of pattern blurring when the pattern is formed on the substrate by the sputtering method.

In the masking material of the above aspect of the present invention, it is preferable that the masking material includes a first mask which has the openings corresponding to the pattern and in which the portions where the openings are not formed have a uniform thickness and a second mask which is configured so as to be mounted on the first mask and in which wall portions are formed in portions corresponding to the boundary portions, and the first and second masks are integrated with each other.

According to the masking material of the above aspect of the present invention, it is possible to form a desired masking material just by disposing the first and second masks in an overlapped manner. Moreover, the first and second masks can be manufactured easily. Therefore, it is possible to form a desired masking material with a simple configuration.

According to still another aspect of the present invention, there is provided a piezoelectric vibrator in which a piezoelectric vibrating reed is sealed in a cavity formed between a base substrate and a lid substrate bonded to each other, in which a pattern formed on the base substrate in the cavity is formed by a sputtering method using the masking material according to any one of the aspects of the present invention.

According to the piezoelectric vibrator of the above aspect of the present invention, since the masking material which is barely bent due to heat is used during the sputtering, the electrode pattern is securely formed at a desired position on the base substrate. Therefore, it is possible to provide a high-quality piezoelectric vibrator having improved yield.

According to still another aspect of the present invention, there is provided a method of manufacturing a piezoelectric vibrator in which a piezoelectric vibrating reed is sealed in a cavity formed between a base substrate and a lid substrate bonded to each other, the method including the steps of: placing the base substrate on a base plate of a substrate supporting jig when forming a pattern on the base substrate, the substrate supporting jig including the base plate on which the base substrate is placed and a magnet plate capable of supporting and fixing a masking material formed of a magnetic material by a magnetic force; placing the masking material according to any one of the aspects of the present invention on the base substrate; and forming a pattern on the base substrate by a sputtering method.

According to the method of manufacturing the piezoelectric vibrator of the above aspect of the present invention, it is possible to support and fix the masking material disposed on the base substrate at a desired position with a simple configuration. Moreover, since the masking material which is barely bent due to heat is used during the sputtering, it is possible to suppress the occurrence of pattern blurring and form the pattern at a desired position on the base substrate. Therefore, it is possible to provide a high-quality piezoelectric vibrator having improved yield.

According to still another aspect of the invention, there is provided an oscillator in which the above-described piezoelectric vibrator is electrically connected to an integrated circuit as an oscillating piece.

According to still another aspect of the invention, there is provided an electronic apparatus in which the above-described piezoelectric vibrator is electrically connected to a clock section.

According to still another aspect of the invention, there is provided a radio-controlled timepiece in which the above-described piezoelectric vibrator is electrically connected to a filter section.

Since each of the oscillator, electronic apparatus, and radio-controlled timepiece of the above aspects of the present invention includes the high-quality piezoelectric vibrator having improved yield, an oscillator, an electronic apparatus, and a radio-controlled timepiece having improved yield and high quality can be provided.

According to the masking material of the above aspect of the present embodiment, since the thickness of the masking material is uniform except for the regions of the openings, even when the temperature of the masking material increases during the sputtering, there is no difference in the amount of thermal expansion in the masking material. Thus, it is possible to prevent the occurrence of bending of the masking material. Accordingly, it is possible to suppress the occurrence of pattern blurring when the pattern is formed on the substrate by the sputtering method.

### BRIEF DESCRIPTION OF THE DRAWINGS

FIG. 1 is a perspective view showing an external appearance of a piezoelectric vibrator according to an embodiment of the present invention.

FIG. 2 is a top view showing an inner structure of the piezoelectric vibrator shown in FIG. 1 when a piezoelectric vibrating reed is viewed from above with a lid substrate removed.

FIG. 3 is a sectional view of the piezoelectric vibrator according to the embodiment of the present invention (taken along the line A-A in FIG. 2).

FIG. 4 is an exploded perspective view of the piezoelectric vibrator shown in FIG. 1.

FIG. 5 is a top view of the piezoelectric vibrating reed that constitutes the piezoelectric vibrator shown in FIG. 1.

FIG. 6 is a bottom view of the piezoelectric vibrating reed shown in FIG. 5.

FIG. 7 is a sectional view taken along the line B-B in FIG. 5.

FIG. 8 is a flowchart showing the flow of the manufacturing process of the piezoelectric vibrator shown in FIG. 1.

FIG. 9 is a view showing one step of the manufacturing process of the piezoelectric vibrator in accordance with the flowchart shown in FIG. 8, showing a state where a plurality of recess portions is formed on a lid substrate wafer serving as a base material of a lid substrate.

FIG. 10 is a view showing one step of the manufacturing process of the piezoelectric vibrator in accordance with the flowchart shown in FIG. 8, showing a state where a plurality of through-holes is formed on a base substrate wafer serving as a base material of a base substrate.

FIG. 11 is a view showing the state shown in FIG. 10 as seen from the cross section of the base substrate wafer.

FIG. 12 is a perspective view of a rivet member according to an embodiment of the present invention.

FIG. 13 is a view showing one step of the manufacturing process of the piezoelectric vibrator in accordance with the flowchart shown in FIG. 8, showing a state where a rivet member is disposed in a through-hole, subsequent to the state shown in FIG. 11.

FIG. 14 is a view showing one step of the manufacturing process of the piezoelectric vibrator in accordance with the flowchart shown in FIG. 8, showing a state where a glass frit is inserted into the through-hole, subsequent to the state shown in FIG. 13.

FIG. 15 is a view showing one step of the manufacturing process of the piezoelectric vibrator in accordance with the flowchart shown in FIG. 8, showing a state where a redundant glass frit is removed, subsequent to the state shown in FIG. 14.

FIG. 16 is a view showing one step of the manufacturing process of the piezoelectric vibrator in accordance with the flowchart shown in FIG. 8, showing a state where a paste is baked and cured, subsequent to the state shown in FIG. 15.

FIG. 17 is a view showing one step of the manufacturing process of the piezoelectric vibrator in accordance with the flowchart shown in FIG. 8, showing a state where the head portion of the rivet member and the surface of the base substrate wafer are polished, subsequent to the state shown in FIG. 16.

FIG. 18 is a view showing one step of the manufacturing process of the piezoelectric vibrator in accordance with the flowchart shown in FIG. 8, showing a state where a penetration electrode forming step is finished.

FIG. 19 is a view showing one step of the manufacturing process of the piezoelectric vibrator in accordance with the flowchart shown in FIG. 8, showing a state where a bonding film and a lead-out electrode are patterned on the upper surface of the base substrate wafer, subsequent to the state shown in FIG. 18.

FIG. 20 is an overall view of the base substrate wafer in the state shown in FIG. 19.

FIG. 21 is a first diagram illustrating a method of patterning the lead-out electrode on the upper surface of the base substrate wafer according to an embodiment of the present invention.

FIG. 22 is a second diagram illustrating a method of patterning the lead-out electrode on the upper surface of the base substrate wafer according to an embodiment of the present invention.

FIG. 23 is a third diagram illustrating a method of patterning the lead-out electrode on the upper surface of the base substrate wafer according to an embodiment of the present invention.

FIG. 24 is an exploded perspective view showing one step of the manufacturing process of the piezoelectric vibrator in accordance with the flowchart shown in FIG. 8, showing a wafer assembly in which the base substrate wafer and the lid substrate wafer are anodically bonded with the piezoelectric vibrating reed accommodated in the cavity.

FIG. 25 is a diagram illustrating another method of patterning the lead-out electrode on the upper surface of the base substrate wafer according to an embodiment of the present invention.

FIG. 26 is a diagram illustrating another shape of the masking material shown in FIG. 25.

FIG. 27 is a view showing the configuration of an oscillator according to an embodiment of the present invention.

FIG. 28 is a view showing the configuration of an electronic apparatus according to an embodiment of the present invention.

FIG. 29 is a view showing the configuration of a radio-controlled timepiece according to an embodiment of the present invention.

FIG. 30 is a top view showing an inner structure of a piezoelectric vibrator of the related art when a piezoelectric vibrating reed is viewed from above with a lid substrate removed.

FIG. 31 is a cross-sectional view of the piezoelectric vibrator shown in FIG. 30.

FIG. 32 is a view showing a method of manufacturing the piezoelectric vibrator of the related art, illustrating a method of patterning the lead-out electrode on the upper surface of the base substrate wafer.

### DETAILED DESCRIPTION OF THE PREFERRED EMBODIMENTS

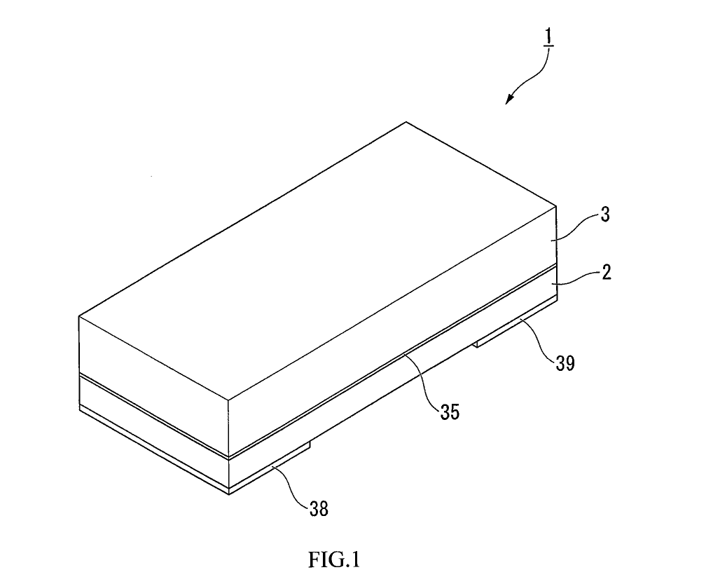

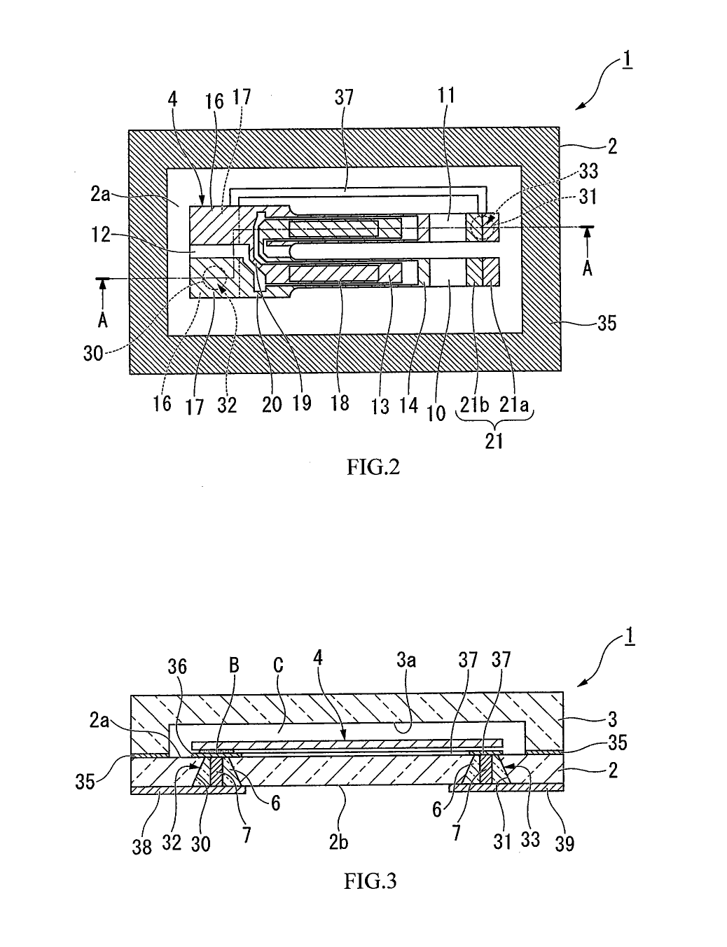

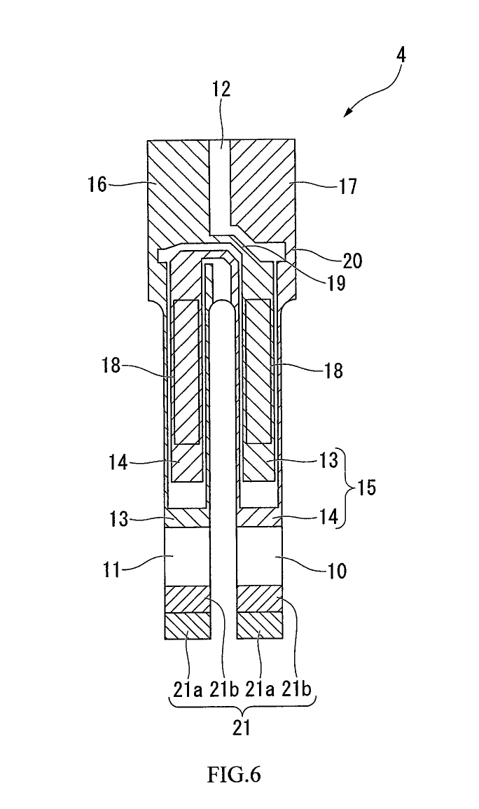

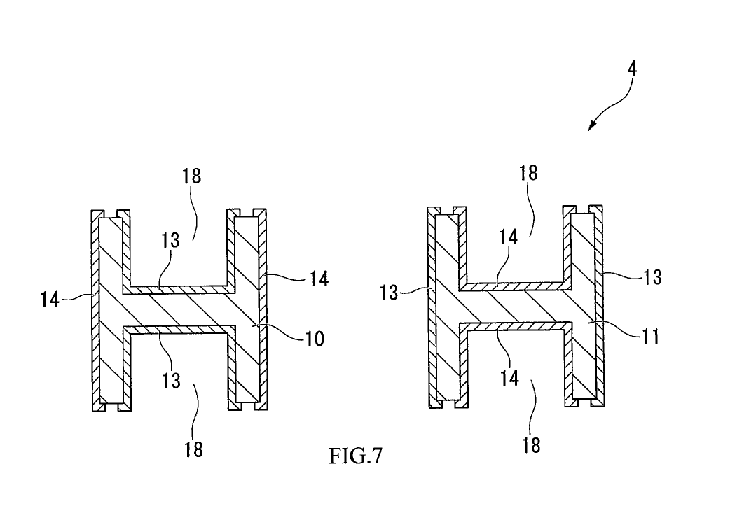

Hereinafter, an embodiment of the present invention will be described with reference to FIGS. 1 to 29.

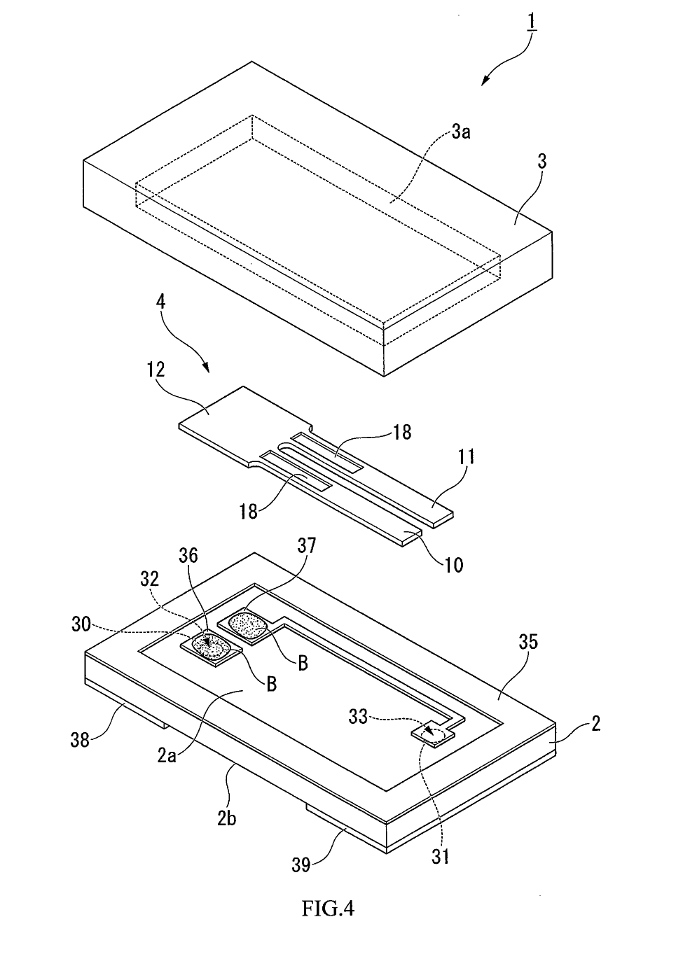

As shown in FIGS. 1 to 4, a piezoelectric vibrator 1 according to the present embodiment is a surface mounted device-type piezoelectric vibrator which is formed in the form of a box laminated in two layers of a base substrate 2 and a lid substrate 3 and in which a piezoelectric vibrating reed 4 is accommodated in a cavity C at an inner portion thereof. In FIG. 4, for better understanding of the drawings, illustrations of excitation electrode 15, extraction electrodes 19 and 20, mount electrodes 16 and 17, and weight metal film 21 of the piezoelectric vibrating reed 4 are omitted.

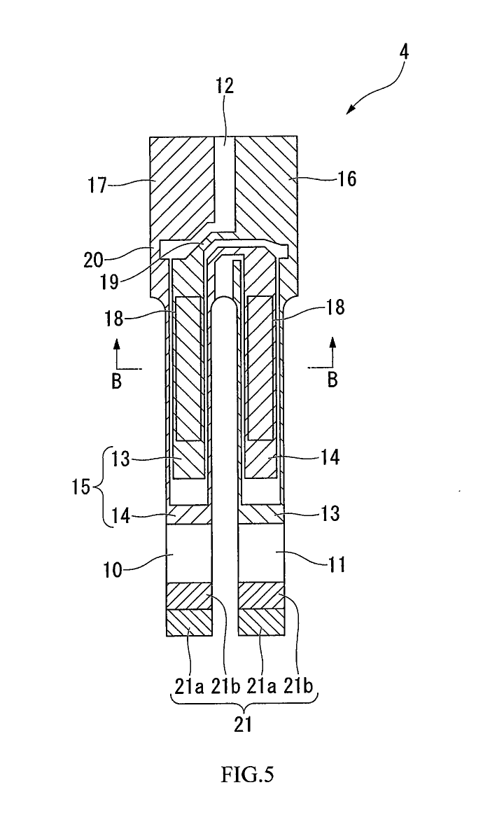

As shown in FIGS. 5 to 7, the piezoelectric vibrating reed 4 is a tuning-fork type vibrating reed which is made of a piezoelectric material such as crystal, lithium tantalate, or lithium niobate and is configured to vibrate when a predetermined voltage is applied thereto.

The piezoelectric vibrating reed 4 includes: a pair of vibrating arms 10 and 11 disposed in parallel to each other; a base portion 12 to which the base end sides of the pair of vibrating arms 10 and 11 are integrally fixed; the excitation electrode 15 which is formed on the outer surfaces of the pair of vibrating arms 10 and 11 so as to allow the pair of vibrating arms 10 and 11 to vibrate and includes a first excitation electrode 13 and a second excitation electrode 14; and the mount electrodes 16 and 17 which are electrically connected to the first excitation electrode 13 and the second excitation electrode 14, respectively.

In addition, the piezoelectric vibrating reed 4 according to the present embodiment is provided with groove portions 18 which are formed on both principal surfaces of the pair of vibrating arms 10 and 11 along the longitudinal direction of the vibrating arms 10 and 11. The groove portions 18 are formed so as to extend from the base end sides of the vibrating arms 10 and 11 up to approximately the middle portions thereof.

The excitation electrode 15 including the first excitation electrode 13 and the second excitation electrode 14 is an electrode that allows the pair of vibrating arms 10 and 11 to vibrate at a predetermined resonance frequency in a direction moving closer to or away from each other and is patterned on the outer surfaces of the pair of vibrating arms 10 and 11 in an electrically isolated state. Specifically, the first excitation electrode 13 is mainly formed on the groove portion 18 of one vibrating arm 10 and both side surfaces of the other vibrating arm 11. On the other hand, the second excitation electrode 14 is mainly formed on both side surfaces of one vibrating arm 10 and the groove portion 18 of the other vibrating arm 11.

Moreover, the first excitation electrode 13 and the second excitation electrode 14 are electrically connected to the mount electrodes 16 and 17 via the extraction electrodes 19 and 20, respectively, on both principal surfaces of the base portion 12. A voltage is applied to the piezoelectric vibrating reed 4 via the mount electrodes 16 and 17.

The above-mentioned excitation electrode 15, mount electrodes 16 and 17, and extraction electrodes 19 and 20 are formed, for example, by a coating of a conductive film made of, for example, such as, chromium (Cr), nickel (Ni), aluminum (Al), or titanium (Ti).

The tip ends of the pair of the vibrating arms 10 and 11 are coated with the weight metal film 21 for adjustment (frequency adjustment) of their own vibration states in a manner such as to vibrate within a predetermined frequency range. The weight metal film 21 is divided into a rough tuning film 21a used for tuning the frequency roughly and a fine tuning film 21b used for tuning the frequency finely. By tuning the frequency with the use of the rough tuning film 21a and the fine tuning film 21b, the frequency of the pair of the vibrating arms 10 and 11 can be set to fall within the range of the nominal frequency of the device.

The piezoelectric vibrating reed 4 configured in this way is bump-bonded to an upper surface 2a of the base substrate 2 by a bump B made of gold or the like as shown in FIGS. 3 and 4. More specifically, bump bonding is achieved in a state where the pair of mount electrodes 16 and 17 come into contact with two bumps B formed on later described lead-out electrodes 36 and 37, respectively, which are patterned on the upper surface 2a of the base substrate 2. In this way, the piezoelectric vibrating reed 4 is supported in a state of being floated from the upper surface 2a of the base substrate 2, and the mount electrodes 16 and 17 and the lead-out electrodes 36 and 37 are electrically connected to each other.

The lid substrate 3 is a transparent insulating substrate made of a glass material, for example, soda-lime glass, and is formed in a substrate-like form as shown in FIGS. 1, 3, and 4. A bonding surface side thereof to be bonded to the base substrate 2 is formed with a rectangular recess portion 3a in which the piezoelectric vibrating reed 4 is accommodated. The recess portion 3a is a recess portion for a cavity serving as the cavity C that accommodates the piezoelectric vibrating reed 4 when the two substrates 2 and 3 are superimposed onto each other. The lid substrate 3 is anodically bonded to the base substrate 2 in a state where the recess portion 3a faces the base substrate 2.

The base substrate 2 is a transparent insulating substrate made of glass material, for example, soda-lime glass, similarly to the lid substrate 3, and is formed in a substrate-like form having a size capable of being overlapped with the lid substrate 3, as shown in FIGS. 1 to 4.

The base substrate 2 is formed with a pair of through-holes (penetration holes) 30 and 31 penetrating through the base substrate 2. At this time, the pair of through-holes 30 and 31 are formed so as to be received in the cavity C. More specifically, the through-holes 30 and 31 of the present embodiment are formed such that one through-hole 30 is positioned close to the base portion 12 of the mounted piezoelectric vibrating reed 4, and the other through-hole 31 is positioned close to the tip ends of the vibrating arms 10 and 11. The present embodiment is described by way of an example of the through-holes which have a tapered sectional shape whose diameter gradually decreases from a lower surface 2b of the base substrate 2 towards the upper surface 2a. However, the present invention is not limited to this example, and the through-holes having an approximately cylindrical shape may be configured to penetrate straight through the base substrate 2. In any case, they only need to penetrate through the base substrate 2.

The pair of through-holes 30 and 31 are formed with a pair of penetration electrodes 32 and 33 which are formed so as to bury the through-holes 30 and 31. As shown in FIG. 3, the penetration electrodes 32 and 33 are formed by a cylindrical member 6 and a core portion 7 which are integrally fixed to the through-holes 30 and 31 by baking. The penetration electrodes 32 and 33 serve to maintain airtightness of the cavity C by completely blocking the through-holes 30 and 31 and achieve electrical connection between outer electrodes 38 and 39 described later and the lead-out electrodes 36 and 37.

The cylindrical member 6 is obtained by baking a paste-like glass frit. The core portion 7 is disposed at the center of the cylindrical member 6 so as to penetrate through the cylindrical member 6. In the present embodiment, the cylindrical member 6 has an approximately conical outer shape (a tapered sectional shape) so as to comply with the shapes of the through-holes 30 and 31. As shown in FIG. 3, the cylindrical member 6 is baked in a state of being buried in the through-holes 30 and 31 and is tightly attached to the through-holes 30 and 31.

The core portion 7 is a conductive cylindrical core material made of metallic material, and similarly to the cylindrical member 6, has a shape which has flat ends and approximately the same thickness as the base substrate 2. As shown in FIG. 3, when the penetration electrodes 32 and 33 are formed as a finished product, the core portion 7 has approximately the same thickness as the base substrate 2 as described above. However, in the course of the manufacturing process, the length of the core portion 7 is slightly smaller (for example, by a distance of 0.02 mm) than the thickness of the base substrate 2 in the initial state of the manufacturing process. The core portion 7 is positioned approximately at the center of the cylindrical member 6 and is tightly attached to the cylindrical member 6 by the baking of the cylindrical member 6. The electrical connection of the penetration electrodes 32 and 33 is secured via the conductive core portion 7.

As shown in FIGS. 1 to 4, on the upper surface 2a side of the base substrate 2 (the bonding surface side to be bonded to the lid substrate 3), a bonding film 35 for anodic bonding and the pair of lead-out electrodes 36 and 37 are patterned by a conductive material such as an aluminum. Among them, the bonding film 35 is formed along the peripheral edge of the base substrate 2 so as to surround the periphery of the recess portion 3a formed on the lid substrate 3.

Moreover, the pair of lead-out electrodes 36 and 37 are patterned so that one penetration electrode 32 of the pair of penetration electrodes 32 and 33 is electrically connected to one mount electrode 16 of the piezoelectric vibrating reed 4, and the other penetration electrode 33 is electrically connected to the other mount electrode 17 of the piezoelectric vibrating reed 4. In the present embodiment, the lead-out electrodes 36 and 37 are formed by mask sputtering. A method of forming the lead-out electrodes 36 and 37 will be described later.

More specifically, one lead-out electrode 36 is formed right above the one penetration electrode 32 to be disposed right below the base portion 12 of the piezoelectric vibrating reed 4. Moreover, the other lead-out electrode 37 is formed to be disposed right above the other penetration electrode 33 after being led out from a position near the one lead-out electrode 36 towards the tip ends of the vibrating arms 10 and 11 along the vibrating arms 10 and 11.

The bumps B are formed on the pair of lead-out electrodes 36 and 37, and the piezoelectric vibrating reed 4 is mounted using the bumps B. In this way, the one mount electrode 16 of the piezoelectric vibrating reed 4 is electrically connected to the one penetration electrode 32 via the bumps B and the one lead-out electrode 36, and the other mount electrode 17 is electrically connected to the other penetration electrode 33 via the bumps B and the other lead-out electrode 37.

Moreover, the outer electrodes 38 and 39 which are electrically connected to the pair of penetration electrodes 32 and 33, respectively, are formed on the lower surface 2b of the base substrate 2, as shown in FIGS. 1, 3, and 4. That is, one outer electrode 38 is electrically connected to the first excitation electrode 13 of the piezoelectric vibrating reed 4 via the one penetration electrode 32 and the one lead-out electrode 36. In addition, the other outer electrode 39 is electrically connected to the second excitation electrode 14 of the piezoelectric vibrating reed 4 via the other penetration electrode 33 and the other lead-out electrode 37.

When the piezoelectric vibrator 1 configured in this manner is operated, a predetermined drive voltage is applied between the pair of outer electrodes 38 and 39 formed on the base substrate 2. In this way, a current can be made to flow to the excitation electrode 15 including the first and second excitation electrodes 13 and 14, of the piezoelectric vibrating reed 4, and the pair of vibrating arms 10 and 11 is allowed to vibrate at a predetermined frequency in a direction moving closer to or away from each other. This vibration of the pair of vibrating arms 10 and 11 can be used as the time source, the timing source of a control signal, the reference signal source, and the like.

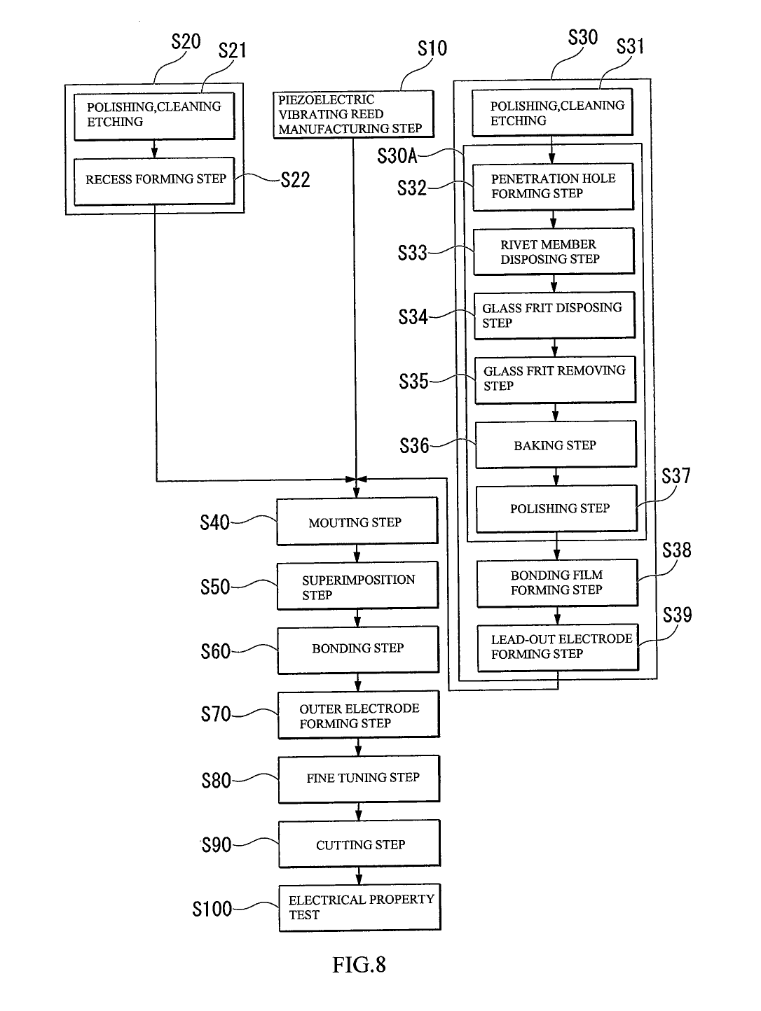

Next, a method for manufacturing a plurality of the above-described piezoelectric vibrators 1 at one time using a base substrate wafer 40 and a lid substrate wafer 50 will be described with reference to the flowchart shown in FIG. 8.

First, a piezoelectric vibrating reed manufacturing step is performed to manufacture the piezoelectric vibrating reed 4 shown in FIGS. 5 to 7 (S10). Specifically, first, a rough crystal Lambert is sliced at a predetermined angle to obtain a wafer having a constant thickness. Subsequently, the wafer is subjected to crude processing by lapping, and an affected layer is removed by etching. Then, the wafer is subjected to mirror processing such as polishing to obtain a wafer having a predetermined thickness. Subsequently, the wafer is subjected to appropriate processing such as washing, and the wafer is patterned so as to have the outer shape of the piezoelectric vibrating reed 4 by a photolithography technique. Moreover, a metal film is formed and patterned on the wafer, thus forming the excitation electrode 15, the extraction electrodes 19 and 20, the mount electrodes 16 and 17, and the weight metal film 21. In this way, a plurality of piezoelectric vibrating reeds 4 can be manufactured.

Moreover, after the piezoelectric vibrating reed 4 is manufactured, rough tuning of a resonance frequency is performed. This rough tuning is achieved by irradiating the rough tuning film 21a of the weight metal film 21 with a laser beam to evaporate in part the rough tuning film 21a, thus changing the weight thereof. Fine tuning of adjusting the resonance frequency more accurately is performed after a mounting step is performed. This fine tuning will be described later.

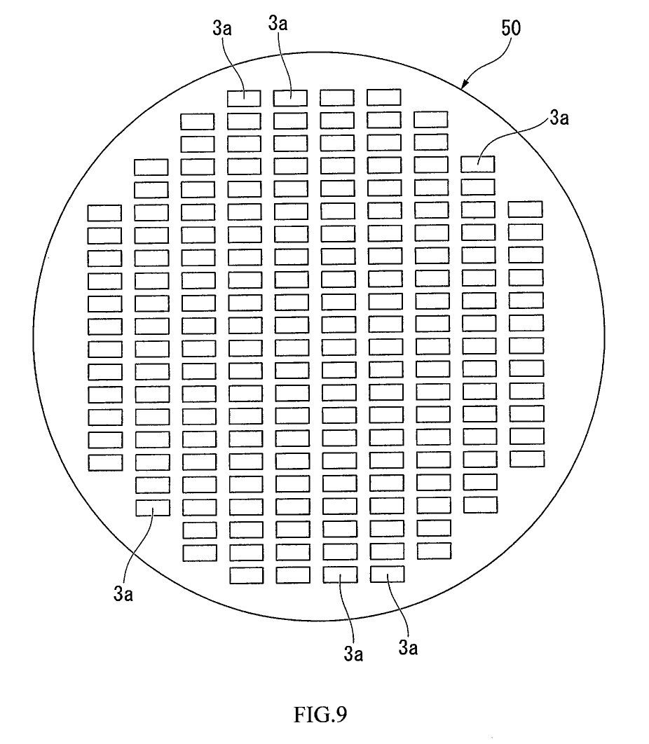

Subsequently, a first wafer manufacturing step is performed where the lid substrate wafer 50 later serving as the lid substrate 3 is manufactured up to a stage immediately before anodic bonding is achieved (S20). In this step, first, a disk-shaped lid substrate wafer 50 is formed as shown in FIG. 9 by polishing a soda-lime glass to a predetermined thickness, cleaning the polished glass, and removing the affected uppermost layer by etching or the like (S21). Subsequently, a recess forming step is performed where a plurality of recess portions 3a to be used as a cavity is formed in a matrix form on the bonding surface of the lid substrate wafer 50 by etching, press working, or the like (S22). The first wafer manufacturing step ends at this point in time.

Subsequently, at the same or a different time as the first wafer manufacturing step, a second wafer manufacturing step is performed where a base substrate wafer 40 later serving as the base substrate 2 is manufactured up to a stage immediately before anodic bonding is achieved (S30). In this step, first, a disk-shaped base substrate wafer 40 is formed by polishing a soda-lime glass to a predetermined thickness, cleaning the polished glass, and removing the affected uppermost layer by etching or the like (S31). Subsequently, a penetration electrode forming step is performed where a plurality of pairs of penetration electrodes 32 and 33 is formed on the base substrate wafer 40 (S30A). The penetration electrode forming step 30A will be described in detail below.

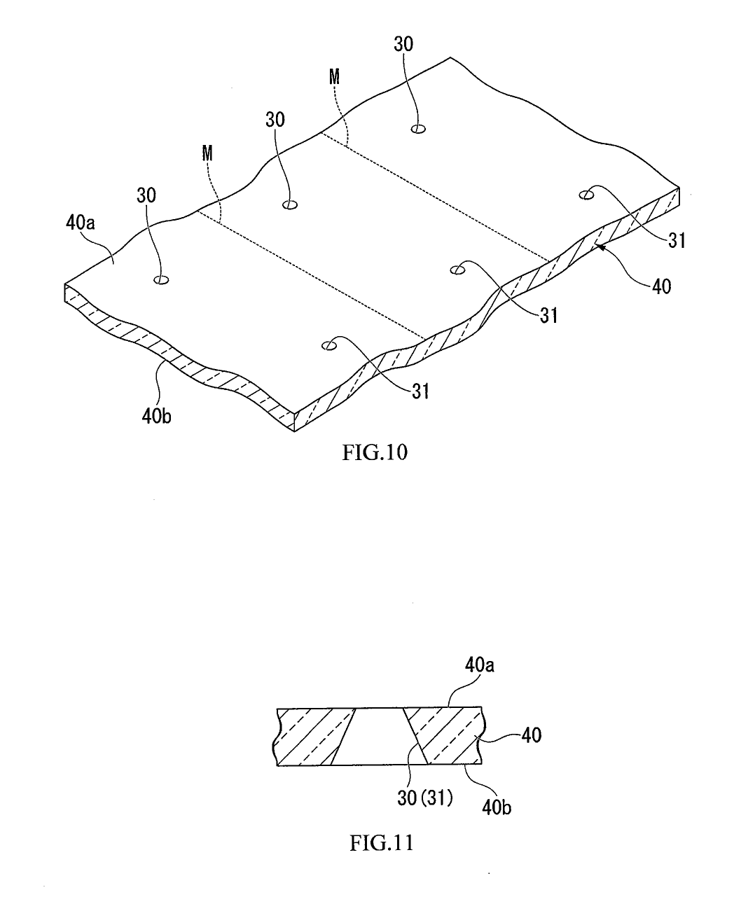

First, as shown in FIG. 10, a penetration hole forming step is performed where a plurality of pairs of through-holes 30 and 31 is formed so as to penetrate through the base substrate wafer 40 (S32). The dotted line M shown in FIG. 10 is a cutting line along which a cutting step performed later is achieved. When this step is performed, the through-holes are formed from a lower surface 40b of the base substrate wafer 40, for example, using a sand blast method. In this way, as shown in FIG. 11, the through-holes 30 and 31 having a tapered sectional shape of which the diameter gradually decreases from the lower surface 40b of the base substrate wafer 40 towards an upper surface 40a can be formed. Moreover, a plurality of pairs of through-holes 30 and 31 is formed so as to be received in the recess portions 3a formed on the lid substrate wafer 50 when the two wafers 40 and 50 are superimposed onto each other later. In addition, the through-holes are formed so that the one through-hole 30 is positioned close to the base portion 12 of the piezoelectric vibrating reed 4, and the other through-hole 31 is positioned close to the tip end side of the vibrating arms 10 and 11.

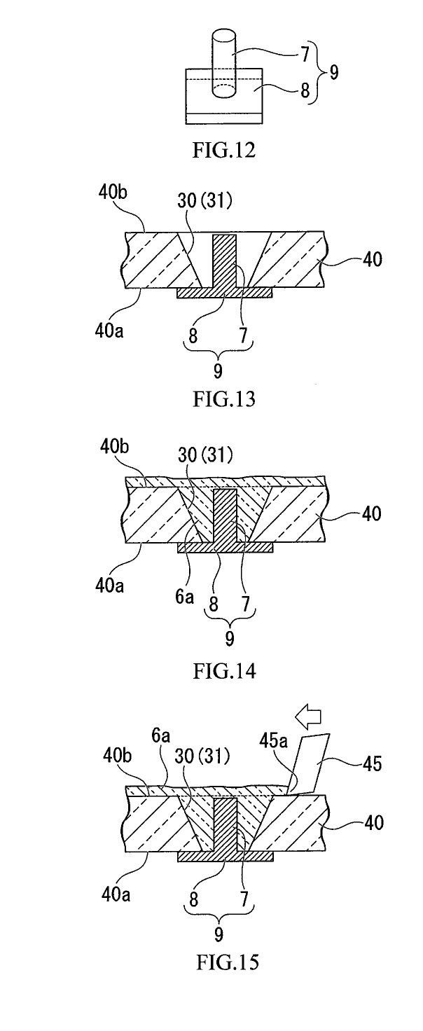

Subsequently, a rivet member disposing step is performed where the core portions 7 of rivet members 9 are disposed in the plurality of through-holes 30 and 31 (S33). At that time, as shown in FIG. 12, a conductive rivet member 9 is used as the rivet member 9, which has a planar head portion 8 and a core portion 7, which extends upwardly from the head portion 8 in a direction approximately perpendicular to the surface of the head portion 8 and has a length shorter by a distance of 0.02 mm than the thickness of the base substrate wafer 40 and a flat tip end. As shown in FIG. 13, the core portion 7 is inserted until the head portion 8 of the rivet member 9 comes into contact with the upper surface 40a of the base substrate wafer 40. Here, it is necessary to dispose the rivet member 9 so that the axial direction of the core portion 7 is approximately identical to the axial direction of the through-holes 30 and 31. However, since the rivet member 9 having the core portion 7 formed on the head portion 8 is used, it is possible to make the axial direction of the core portion 7 identical to the axial direction of the through-holes 30 and 31 by a simple operation of pushing the rivet member 9 until the head portion 8 comes into contact with the upper surface 40a of the base substrate wafer 40. Therefore, it is possible to improve workability during the setting step. Since the head portion 8 has a planar shape, the base substrate wafer 40 can be placed stably on a flat surface of a desk or the like without any rattling during periods between the penetration electrode alignment step and a baking step performed later. In this respect, it is possible to achieve an improvement in the workability.

Subsequently, as shown in FIG. 14, a glass frit insertion step is performed where a paste-like glass frit 6a made of a glass material is inserted into the through-holes 30 and 31 (S34). In order to insert the glass frit 6a in the through-holes 30 and 31, the glass frit 6a is inserted from a side of the through-holes 30 and 31 close to the lower surface 40b of the base substrate wafer 40. At that time, a sufficient amount of the glass frit 6a is applied so that the glass frit 6a is securely inserted into the through-holes 30 and 31. Therefore, the glass frit 6a is also applied onto the lower surface 40b of the base substrate wafer 40. When the glass frit 6a is baked in this state, since a subsequent polishing step may take a lot of time, a glass frit removal step is performed so as to remove the redundant glass frit 6a before the baking (S35).

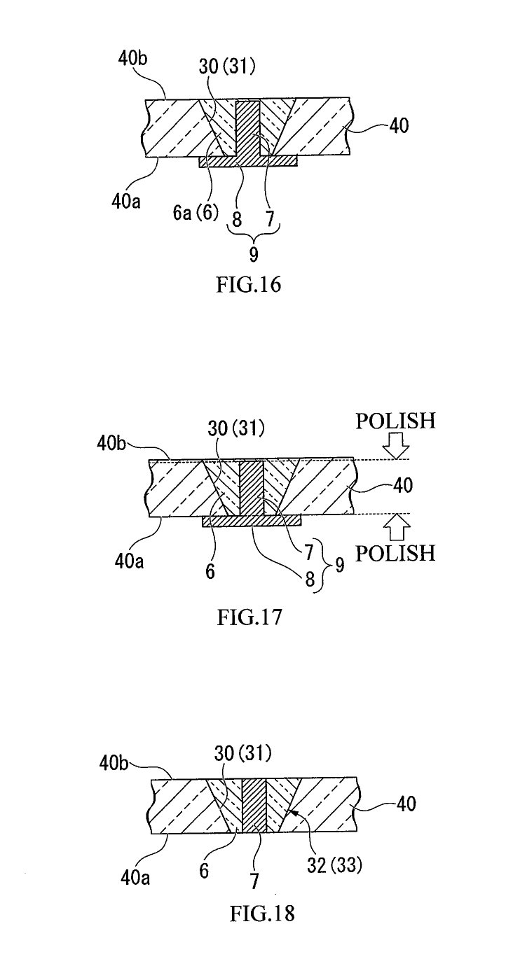

As shown in FIG. 15, in the glass frit removal step, the glass frit 6a protruding from the through-holes 30 and 31 is removed by moving a squeegee 45 made of resin, for example, along the surface of the base substrate wafer 40 with a tip end 45a of the squeegee 45 coming into contact with the surface of the base substrate wafer 40. By doing so, as shown in FIG. 16, the redundant glass frit 6a can be removed securely by a simple operation. In the present embodiment, the length of the core portion 7 of the rivet member 9 is smaller by a distance of 0.02 mm than the thickness of the base substrate wafer 40. Therefore, when the squeegee 45 passes over the through-holes 30 and 31, the tip end 45a of the squeegee 45 will not make contact with the tip end of the core portion 7. Thus, it is possible to prevent the core portion 7 from being tilted.

Subsequently, a baking step is performed where the glass frit 6a inserted into the through-holes 30 and 31 is baked at a predetermined temperature (S36). Through the baking step, the through-holes 30 and 31, the glass frit 6a buried in the through-holes 30 and 31, and the rivet members 9 disposed in the glass frit 6a are attached to each other. Since the baking is performed as a whole including the head portions 8, the through-holes 30 and 31 and the rivet members 9 can be integrally fixed to each other in a state where the axial direction of the core portion 7 is approximately identical to the axial direction of the through-holes 30 and 31. The baked glass frit 6a is solidified as the cylindrical member 6.

Subsequently, as shown in FIG. 17, a polishing step is performed where the head portions 8 of the rivet members 9 are polished and removed (S37). In this way, it is possible to remove the head portions 8 that achieved positioning of the cylindrical member 6 and the core portions 7 and allow only the core portions 7 to remain inside the cylindrical member 6.

At the same time, the lower surface 40b of the base substrate wafer 40 is polished to obtain a flat surface. The polishing is continued until the tip end of the core portion 7 is exposed. As a result, as shown in FIG. 18, it is possible to obtain a plurality of pairs of penetration electrodes 32 and 33 in which the cylindrical member 6 and the core portion 7 are integrally fixed.

As described above, the surfaces (the upper and lower surfaces 40a and 40b) of the base substrate wafer 40 are approximately flush with both ends of the cylindrical member 6 and the core portion 7. That is, it is possible to make the surfaces of the base substrate wafer 40 approximately flush with the surfaces of the penetration electrodes 32 and 33. The penetration electrode forming step S30A ends at the point of time when the polishing step is performed.

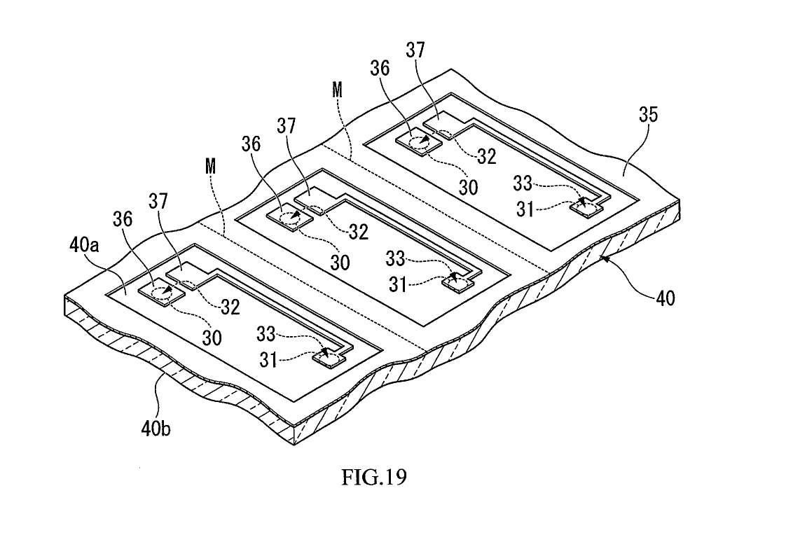

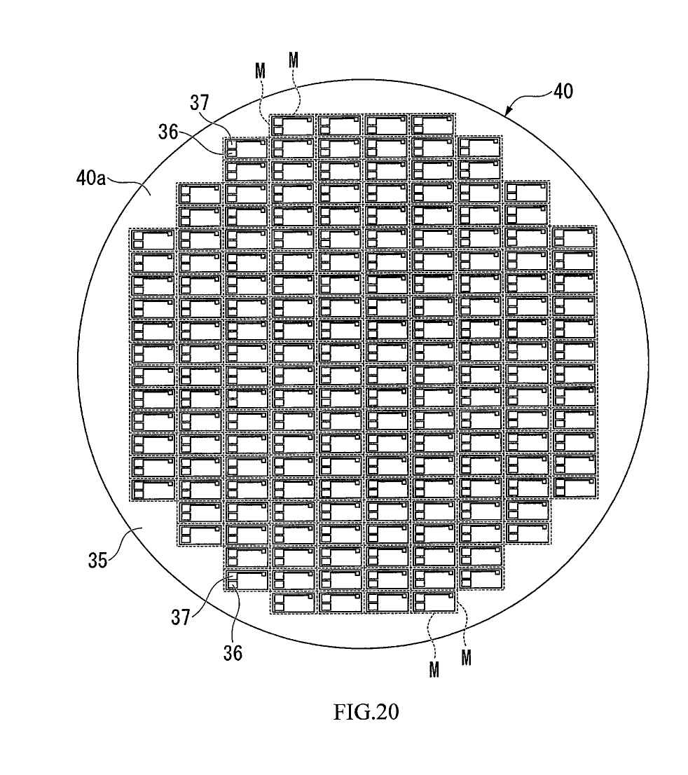

Subsequently, a bonding film forming step is performed where a conductive material is patterned on the upper surface 40a of the base substrate wafer 40 so as to form a bonding film 35 as shown in FIGS. 19 and 20 (S38). Moreover, a lead-out electrode forming step is performed where a plurality of lead-out electrodes 36 and 37 is formed so as to be electrically connected to each pair of penetration electrodes 32 and 33, respectively (S39). The dotted line M shown in FIGS. 19 and 20 is a cutting line along which a cutting step performed later is achieved.

Here, the lead-out electrode forming step will be described further in detail.

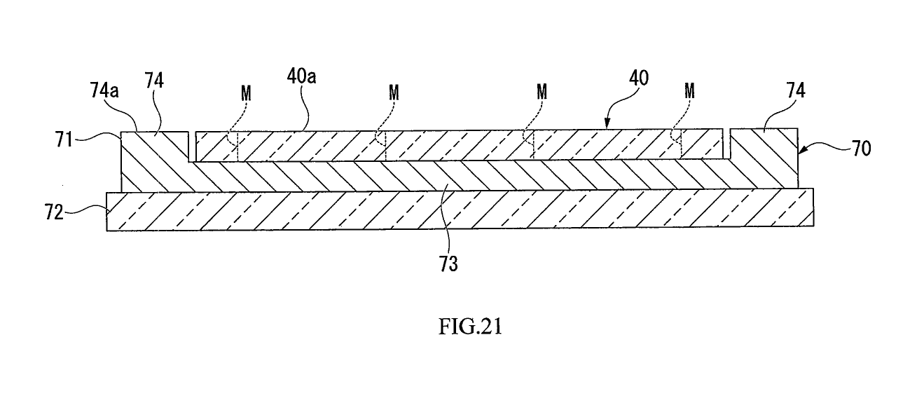

In the present embodiment, the lead-out electrodes 36 and 37 are formed on the base substrate wafer 40 by using a sputtering method. Specifically, as shown in FIG. 21, the base substrate wafer 40 is placed on a substrate supporting jig 70 so that the base substrate wafer 40 moves inside a sputtering machine. The substrate supporting jig 70 includes a base plate 71 on which the base substrate wafer 40 is placed, and a magnet plate 72 capable of supporting and fixing a masking material 80 formed of a magnetic material by a magnetic force. The base plate 71 includes a planar portion 73 having a size capable of mounting the base substrate wafer 40 and a peripheral portion 74 constituting the periphery of the planar portion 73. The peripheral portion 74 is thicker than the planar portion 73. That is, a region where the base substrate wafer 40 is placed is concave. The thickness of the base substrate wafer 40 is approximately the same as the height (thickness) of the peripheral portion 74, and the upper surface 40a of the base substrate wafer 40 is approximately flush with the upper surface 74a of the peripheral portion 74 in a state where the base substrate wafer 40 is placed on the planar portion 73.

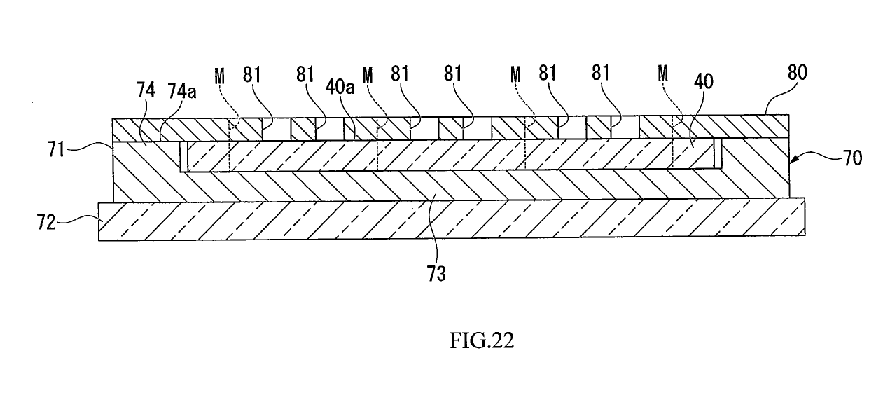

Subsequently, as shown in FIG. 22, the masking material 80 is placed so as to cover the base substrate wafer 40 and the peripheral portion 74 of the base plate 71. The outer shape of the masking material 80 is approximately the same as the outer shape of the base plate 71 in top view. Moreover, since the masking material 80 is formed, for example, of a magnetic material such as stainless steel, the masking material 80 is supported and fixed to the magnet plate 72. On the masking material 80, a plurality of openings 81 is formed so as to have the shape corresponding to the lead-out electrodes 36 and 37. The masking material 80 of the present embodiment is formed so that the portions where the openings 81 are not formed have a uniform thickness. That is, the masking material 80 is formed by just forming the openings 81 on a planar member having a uniform thickness.

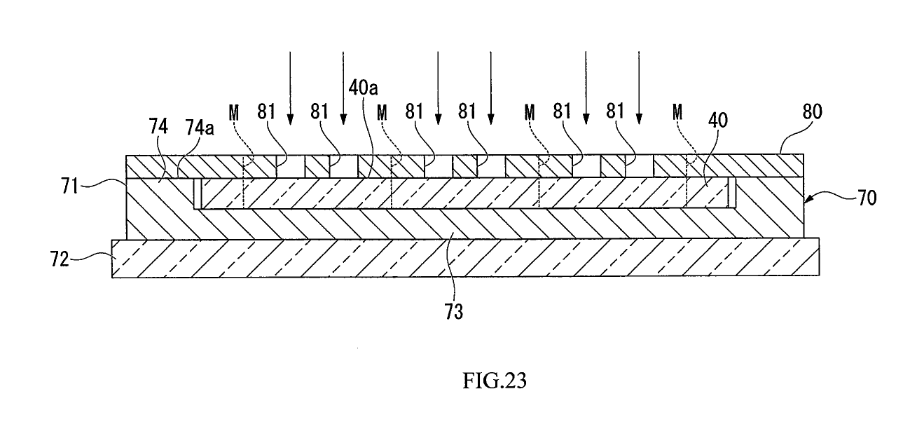

Subsequently, as shown in FIG. 23, the substrate supporting jig 70 is moved into a sputtering machine (not shown) with the masking material 80 supported and fixed thereto, and the lead-out electrodes 36 and 37 are formed on the upper surface 40a of the base substrate wafer 40 by a sputtering method. At that time, although the masking material 80 may be bent due to heat, since the masking material 80 of the present embodiment has a uniform thickness, there is no difference in the amount of thermal expansion in the masking material 80. Therefore, it is possible to suppress the occurrence of bending of the masking material 80 and form the lead-out electrodes 36 and 37 at a desired position of the base substrate wafer 40.

Particularly, as described above, the penetration electrodes 32 and 33 are approximately flush with the upper surface 40a of the base substrate wafer 40. Therefore, the lead-out electrodes 36 and 37 which are patterned on the upper surface 40a of the base substrate wafer 40 are closely adhered to the penetration electrodes 32 and 33 without forming any gap or the like therebetween. In this way, it is possible to achieve reliable electrical connection between the one lead-out electrode 36 and the one penetration electrode 32 and reliable electrical connection between the other lead-out electrode 37 and the other penetration electrode 33. The second wafer manufacturing step ends at this point in time.

In FIG. 8, although the lead-out electrode forming step (S39) is performed after the bonding film forming step (S38), conversely, the bonding film forming step (S38) may be performed after the lead-out electrode forming step (S39), and the two steps may be performed at the same time. The same operational effect can be obtained with any order of the steps. Therefore, the order of the steps may be appropriately changed as necessary. Moreover, the bonding film 35 can be formed by a sputtering method using the masking material and the substrate supporting jig having the same configuration as above.

Subsequently, a mounting step is performed where a plurality of manufactured piezoelectric vibrating reeds 4 is bonded to the upper surface 40a of the base substrate wafer 40 with the lead-out electrodes 36 and 37 disposed therebetween (S40). First, bumps B made of gold or the like are formed on the pair of lead-out electrodes 36 and 37. The base portion 12 of the piezoelectric vibrating reed 4 is placed on the bumps B, and thereafter the piezoelectric vibrating reed 4 is pressed against the bumps B while heating the bumps B to a predetermined temperature. In this way, the piezoelectric vibrating reed 4 is mechanically supported by the bumps B, and the mount electrodes 16 and 17 are electrically connected to the lead-out electrodes 36 and 37. Therefore, at this point in time, the pair of excitation electrodes 15 of the piezoelectric vibrating reed 4 is electrically connected to the pair of penetration electrodes 32 and 33, respectively. Particularly, since the piezoelectric vibrating reed 4 is bump-bonded, the piezoelectric vibrating reed 4 is supported in a state of being floated from the upper surface 40a of the base substrate wafer 40.

After the piezoelectric vibrating reed 4 is mounted, a superimposition step is performed where the lid substrate wafer 50 is superimposed onto the base substrate wafer 40 (S50). Specifically, both wafers 40 and 50 are aligned at a correct position using reference marks or the like not shown in the figure as indices. In this way, the mounted piezoelectric vibrating reed 4 is accommodated in the recess portion 3a formed on the base substrate wafer 40, namely in the cavity C which is surrounded by the two wafers 40 and 50.

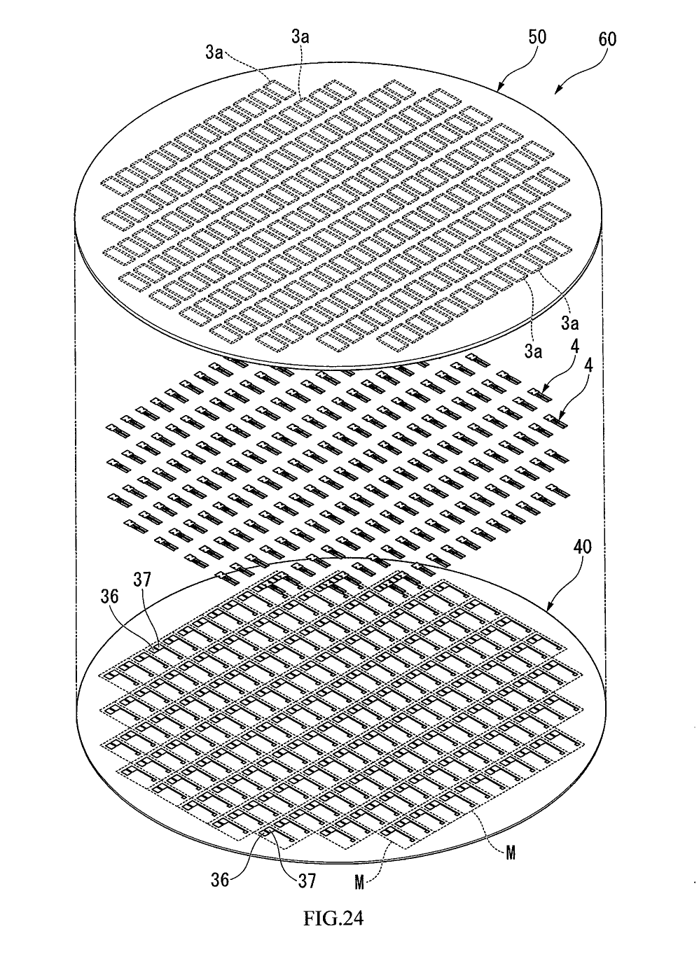

After the superimposition step is performed, a bonding step is performed where the two superimposed wafers 40 and 50 are inserted into an anodic bonding machine (not shown) to achieve anodic bonding under a predetermined temperature atmosphere with application of a predetermined voltage (S60). Specifically, a predetermined voltage is applied between the bonding film 35 and the lid substrate wafer 50. Then, an electrochemical reaction occurs at an interface between the bonding film 35 and the lid substrate wafer 50, whereby they are closely and tightly adhered and anodically bonded. In this way, the piezoelectric vibrating reed 4 can be sealed in the cavity C, and a wafer assembly 60 shown in FIG. 24 can be obtained in which the base substrate wafer 40 and the lid substrate wafer 50 are bonded to each other. In FIG. 24, for better understanding of the figure, the wafer assembly 60 is illustrated in an exploded state, and illustration of the bonding film 35 is omitted from the base substrate wafer 40. The dotted line M shown in FIG. 24 is a cutting line along which a cutting step performed later is achieved.

When the anodic bonding is performed, since the through-holes 30 and 31 formed on the base substrate wafer 40 are completely blocked by the penetration electrodes 32 and 33, the airtightness in the cavity C will not be impaired by the through-holes 30 and 31. Particularly, since the cylindrical member 6 and the core portion 7 are integrally fixed by the baking, and they are tightly attached to the through-holes 30 and 31, it is possible to reliably maintain airtightness in the cavity C.

After the above-described anodic bonding is completed, an outer electrode forming step is performed where a conductive material is patterned onto the lower surface 40b of the base substrate wafer 40 so as to form a plurality of pairs of outer electrodes 38 and 39 which is electrically connected to the pair of penetration electrodes 32 and 33 (S70). Through this step, the piezoelectric vibrating reed 4 which is sealed in the cavity C can be operated using the outer electrodes 38 and 39.

Particularly, when this step is performed, similarly to the step of forming the lead-out electrodes 36 and 37, since the penetration electrodes 32 and 33 are approximately flush with the lower surface 40b of the base substrate wafer 40, the patterned outer electrodes 38 and 39 are closely adhered onto the penetration electrodes 32 and 33 without forming any gap or the like therebetween. In this way, it is possible to achieve reliable electrical connection between the outer electrodes 38 and 39 and the penetration electrodes 32 and 33.

Subsequently, a fine tuning step is performed on the wafer assembly 60 where the frequencies of the individual piezoelectric vibrators 1 sealed in the cavities C are tuned finely to fall within a predetermined range (S80). Specifically, a voltage is applied to the pair of outer electrodes 38 and 39 which are formed on the lower surface 40b of the base substrate wafer 40, thus allowing the piezoelectric vibrating reeds 4 to vibrate. A laser beam is irradiated onto the lid substrate wafer 50 from the outer side while measuring the vibration frequencies to evaporate the fine tuning film 21b of the weight metal film 21. In this way, since the weight on the tip end sides of the pair of vibrating arms 10 and 11 is changed, the fine tuning can be performed in such a way that the frequency of the piezoelectric vibrating reed 4 falls within the predetermined range of the nominal frequency.

After the fine tuning of the frequency is completed, a cutting step is performed where the bonded wafer assembly 60 is cut along the cutting line M shown in FIG. 24 to obtain small fragments (S90). As a result, a plurality of two-layered surface mounted device-type piezoelectric vibrators 1 shown in FIG. 1, in which the piezoelectric vibrating reed 4 is sealed in the cavity C formed between the base substrate 2 and the lid substrate 3 being anodically bonded together, can be manufactured at one time.

The fine tuning step (S80) may be performed after performing the cutting step (S90) to obtain the individual fragmented piezoelectric vibrators 1. However, as described above, by performing the fine tuning step (S80) earlier, since the fine tuning step can be performed on the wafer assembly 60, it is possible to perform the fine tuning on the plurality of piezoelectric vibrators 1 more efficiently. Therefore, it is desirable because throughput can be increased.

Subsequently, an inner electrical property test is conducted (S100). That is, the resonance frequency, resonance resistance value, drive level properties (the excitation power dependence of the resonance frequency and the resonance resistance value), and the like of the piezoelectric vibrating reed 4 are measured and checked. Moreover, the insulation resistance value properties and the like are compared and checked as well. Finally, an external appearance test of the piezoelectric vibrator 1 is conducted to check the dimensions, the quality, and the like. In this way, the manufacturing of the piezoelectric vibrator 1 ends.

According to the present embodiment, the thickness of the masking material 80 used when forming the lead-out electrodes 36 and 37 on the base substrate wafer 40 by a sputtering method is uniform except for the regions of the openings 81. Therefore, even when the temperature of the masking material 80 increases during the sputtering, there is no difference in the amount of thermal expansion in the masking material 80. Thus, it is possible to prevent the occurrence of bending of the masking material 80. Accordingly, it is possible to suppress the occurrence of blurring in the electrode pattern when the lead-out electrodes 36 and 37 are formed on the base substrate wafer 40 by the sputtering method.

Moreover, the base substrate wafer 40 is placed on the base plate 71 of the substrate supporting jig 70 which is used for moving the base substrate wafer 40 into a sputtering machine, and the masking material 80 is supported and fixed to the magnet plate 72. Therefore, it is possible to support and fix the masking material 80 disposed on the base substrate wafer 40 at a desired position with a simple configuration. Moreover, since the masking material 80 which is barely bent due to heat is used, it is possible to suppress the occurrence of blurring of the electrode pattern when the lead-out electrodes 36 and 37 are formed on the base substrate wafer 40 by the sputtering method.

Moreover, in the piezoelectric vibrator 1 in which the lead-out electrodes 36 and 37 are formed using the masking material 80 and the substrate supporting jig 70, the lead-out electrodes 36 and 37 are formed at a desired position on the base substrate 2. Therefore, it is possible to provide the high-quality piezoelectric vibrator 1 having improved yield.

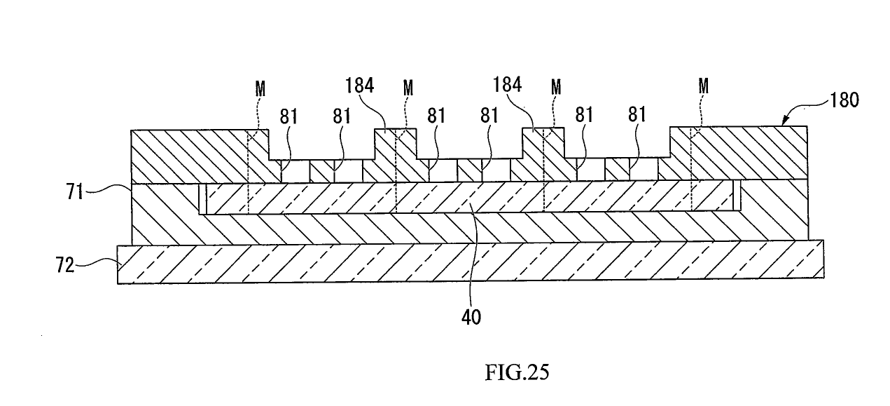

As shown in FIG. 25, a masking material 180 having a different shape from the masking material 80 may be used. The outer shape of the masking material 180 is approximately the same as the outer shape of the base plate 71 in top view. Moreover, since the masking material 180 is formed, for example, of a magnetic material such as stainless steel, the masking material 180 is supported and fixed to the magnet plate 72. On the masking material 80, a plurality of openings 81 is formed so as to have the shape corresponding to the lead-out electrodes 36 and 37. Moreover, boundary portions 184 of the adjacent fragments, namely the portions corresponding to the cutting lines M have approximately the same thicknesses as the thickness at a position corresponding to the peripheral portion of the base substrate wafer 40 (the position corresponds to the peripheral portion 74 of the base plate 71). That is, the thicknesses of only the portions where the openings 81 are formed and the proximities thereof are thin, and the other portions have a uniform thickness.

With this configuration, it is also possible to suppress the occurrence of bending of the masking material 180 due to a difference in the amount of thermal expansion as described above. Accordingly, it is possible to suppress the occurrence of blurring in the electrode pattern when the lead-out electrodes 36 and 37 are formed on the base substrate wafer 40 by the sputtering method.

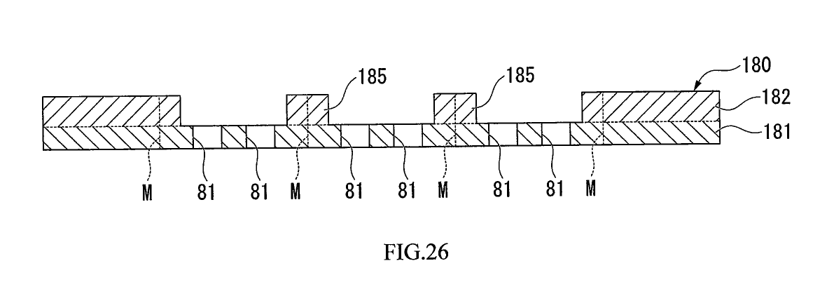

The masking material 180 may be formed integrally using stainless steel, for example. Alternatively, as shown in FIG. 26, the masking material 180 may be formed by stacking a first mask 181 which has the openings 81 and in which portions where the openings 81 are not formed have a uniform thickness and a second mask 182 which is configured so as to be mounted on the first mask 181 and in which wall portions 185 are formed in portions corresponding to the boundary portions (cutting lines M). By doing so, the masking material 180 can form a desired masking material 180 just by disposing the first mask 181 and the second mask 182 in an overlapped manner. Moreover, the first and second masks 181 and 182 can be manufactured easily. Therefore, it is possible to configure a desired masking material 180 with a simple configuration.

### Oscillator

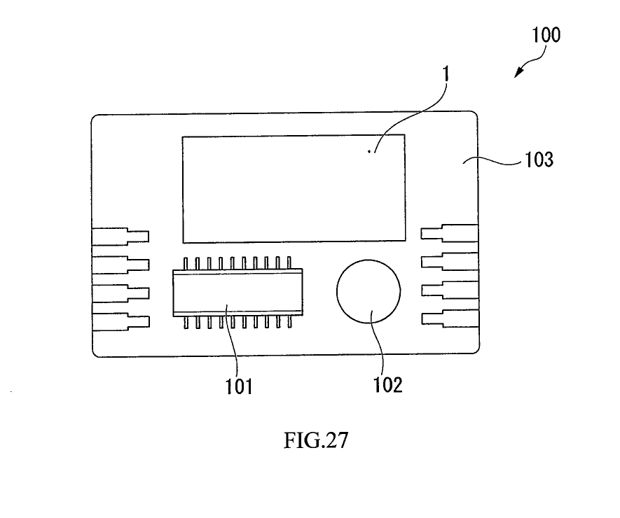

Next, an oscillator according to another embodiment of the invention will be described with reference to FIG. 27.

In an oscillator 100 according to the present embodiment, the piezoelectric vibrator 1 is used as an oscillating piece electrically connected to an integrated circuit 101, as shown in FIG. 27. The oscillator 100 includes a substrate 103 on which an electronic component 102, such as a capacitor, is mounted. The integrated circuit 101 for an oscillator is mounted on the substrate 103, and the piezoelectric vibrator 1 is mounted near the integrated circuit 101. The electronic component 102, the integrated circuit 101, and the piezoelectric vibrator 1 are electrically connected to each other by a wiring pattern (not shown). In addition, each of the constituent components is molded with a resin (not shown).

In the oscillator 100 configured as described above, when a voltage is applied to the piezoelectric vibrator 1, the piezoelectric vibrating reed 4 in the piezoelectric vibrator 1 vibrates. This vibration is converted into an electrical signal due to the piezoelectric property of the piezoelectric vibrating reed 4 and is then input to the integrated circuit 101 as the electrical signal. The input electrical signal is subjected to various kinds of processing by the integrated circuit 101 and is then output as a frequency signal. In this way, the piezoelectric vibrator 1 functions as an oscillating piece.

Moreover, by selectively setting the configuration of the integrated circuit 101, for example, an RTC (real time clock) module, according to the demands, it is possible to add a function of controlling the operation date or time of the corresponding device or an external device or of providing the time or calendar in addition to a single functional oscillator for a clock.

As described above, since the oscillator 100 according to the present embodiment includes the high-quality piezoelectric vibrator 1 having an improved yield, it is possible to achieve an improvement in the operational reliability and high quality of the oscillator 100 itself which provides stable conductivity. In addition to this, it is possible to obtain a highly accurate frequency signal which is stable over a long period of time.

### Electronic Apparatus

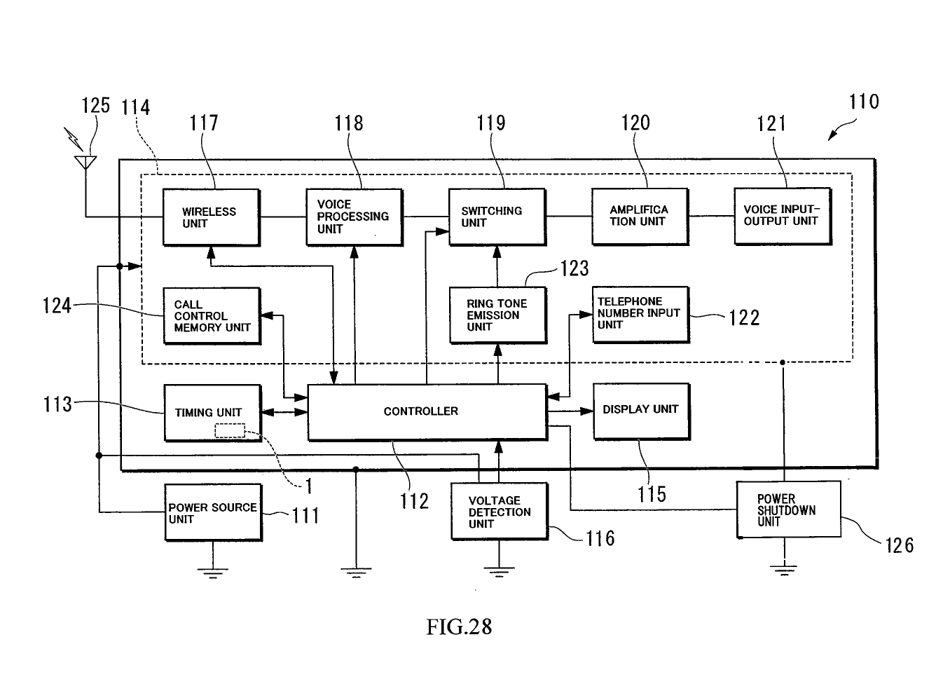

Next, an electronic apparatus according to another embodiment of the invention will be described with reference to FIG. 28. In addition, a portable information device 110 including the piezoelectric vibrator 1 described above will be described as an example of an electronic apparatus.

The portable information device 110 according to the present embodiment is represented by a mobile phone, for example, and has been developed and improved from a wristwatch in the related art. The portable information device 110 is similar to a wristwatch in external appearance, and a liquid crystal display is disposed in a portion equivalent to a dial pad so that a current time and the like can be displayed on this screen. Moreover, when it is used as a communication apparatus, it is possible to remove it from the wrist and to perform the same communication as a mobile phone in the related art with a speaker and a microphone built into an inner portion of the band. However, the portable information device 110 is very small and light compared with a mobile phone in the related art.

Next, the configuration of the portable information device 110 according to the present embodiment will be described. As shown in FIG. 28, the portable information device 110 includes the piezoelectric vibrator 1 and a power supply section 111 for supplying power. The power supply section 111 is formed of a lithium secondary battery, for example. A control section 112 which performs various kinds of control, a clock section 113 which performs measuring of time and the like, a communication section 114 which performs communication with the outside, a display section 115 which displays various kinds of information, and a voltage detecting section 116 which detects the voltage of each functional section are connected in parallel to the power supply section 111. In addition, the power supply section 111 supplies power to each functional section.

The control section 112 controls an operation of the entire system. For example, the control section 112 controls each functional section to transmit and receive the audio data or to measure or display a current time. In addition, the control section 112 includes a ROM in which a program is written in advance, a CPU which reads and executes a program written in the ROM, a RAM used as a work area of the CPU, and the like.

The clock section 113 includes an integrated circuit, which has an oscillation circuit, a register circuit, a counter circuit, and an interface circuit therein, and the piezoelectric vibrator 1. When a voltage is applied to the piezoelectric vibrator 1, the piezoelectric vibrating reed 4 vibrates, and this vibration is converted into an electrical signal due to the piezoelectric property of crystal and is then input to the oscillation circuit as the electrical signal. The output of the oscillation circuit is binarized to be counted by the register circuit and the counter circuit. Then, a signal is transmitted to or received from the control section 112 through the interface circuit, and current time, current date, calendar information, and the like are displayed on the display section 115.

The communication section 114 has the same function as a mobile phone in the related art, and includes a wireless section 117, an audio processing section 118, a switching section 119, an amplifier section 120, an audio input/output section 121, a telephone number input section 122, a ring tone generating section 123, and a call control memory section 124.

The wireless section 117 transmits/receives various kinds of data, such as audio data, to/from the base station through an antenna 125. The audio processing section 118 encodes and decodes an audio signal input from the wireless section 117 or the amplifier section 120. The amplifier section 120 amplifies a signal input from the audio processing section 118 or the audio input/output section 121 up to a predetermined level. The audio input/output section 121 is formed by a speaker, a microphone, and the like, and amplifies a ring tone or incoming sound louder or collects the sound.

In addition, the ring tone generating section 123 generates a ring tone in response to a call from the base station. The switching section 119 switches the amplifier section 120, which is connected to the audio processing section 118, to the ring tone generating section 123 only when a call arrives, so that the ring tone generated in the ring tone generating section 123 is output to the audio input/output section 121 through the amplifier section 120.

In addition, the call control memory section 124 stores a program related to incoming and outgoing call control for communications. Moreover, the telephone number input section 122 includes, for example, numeric keys from 0 to 9 and other keys. A user inputs a telephone number of a communication destination by pressing these numeric keys and the like.

The voltage detecting section 116 detects a voltage drop when a voltage, which is applied from the power supply section 111 to each functional section, such as the control section 112, drops below the predetermined value, and notifies the control section 112 of the detection. In this case, the predetermined voltage value is a value which is set beforehand as a lowest voltage necessary to operate the communication section 114 stably. For example, it is about 3 V. When the voltage drop is notified from the voltage detecting section 116, the control section 112 disables the operation of the wireless section 117, the audio processing section 118, the switching section 119, and the ring tone generating section 123. In particular, the operation of the wireless section 117 that consumes a large amount of power should be necessarily stopped. In addition, a message informing that the communication section 114 is not available due to insufficient battery power is displayed on the display section 115.

That is, it is possible to disable the operation of the communication section 114 and display the notice on the display section 115 by the voltage detecting section 116 and the control section 112. This message may be a character message. Or as a more intuitive indication, a cross mark (X) may be displayed on a telephone icon displayed at the top of the display screen of the display section 115.

In addition, the function of the communication section 114 can be more reliably stopped by providing a power shutdown section 126 capable of selectively shutting down the power of a section related to the function of the communication section 114.

As described above, since the portable information device 110 according to the present embodiment includes the high-quality piezoelectric vibrator 1 having improved yield, it is possible to achieve an improvement in the operational reliability and high quality of the portable information device 110 itself which provides stable conductivity. In addition to this, it is possible to display highly accurate clock information which is stable over a long period of time.

### Radio-Controlled Timepiece

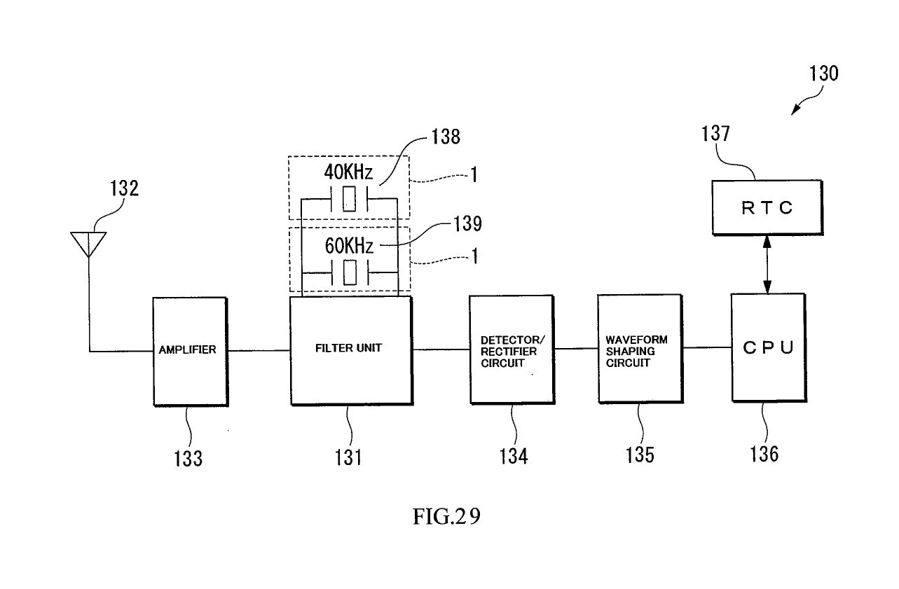

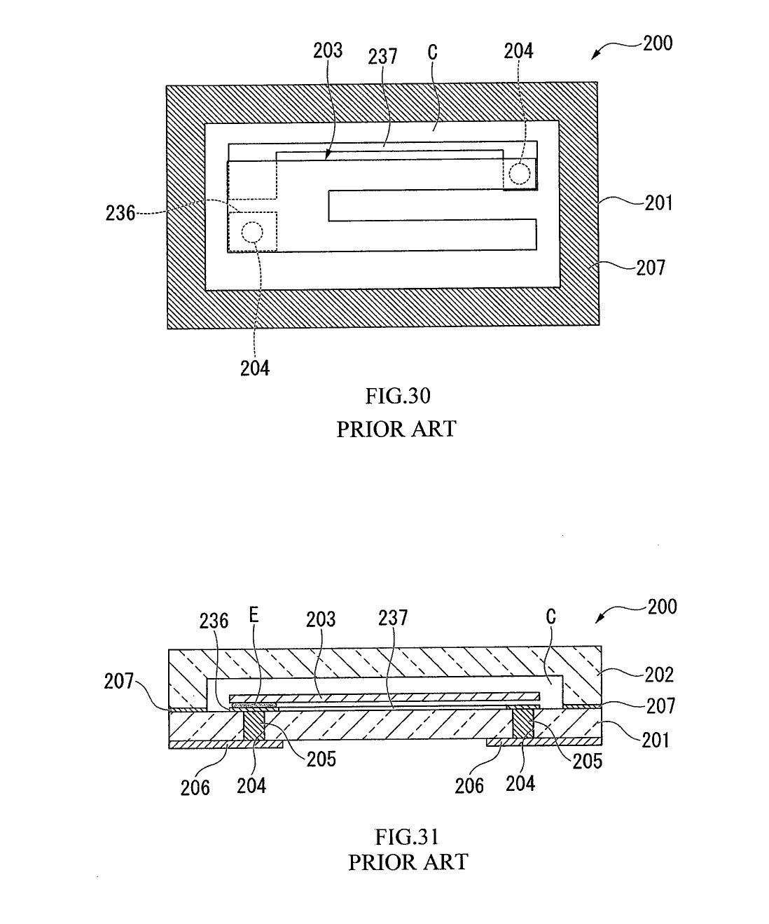

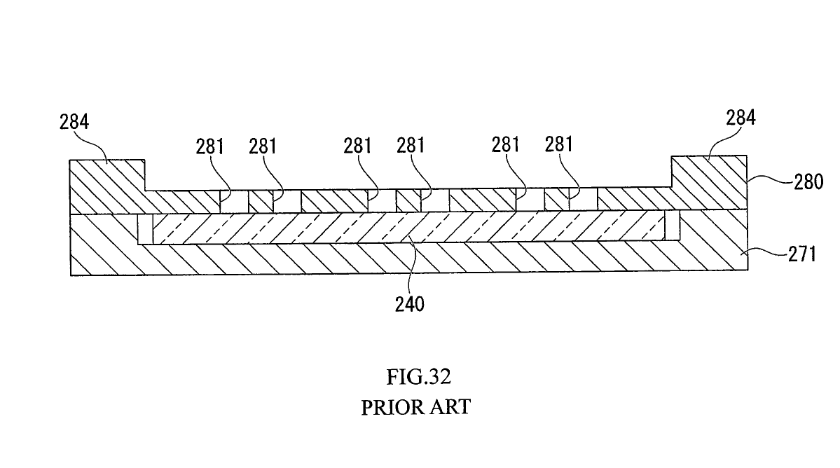

Next, a radio-controlled timepiece according to still another embodiment of the invention will be described with reference to FIG. 29.

As shown in FIG. 29, a radio-controlled timepiece 130 according to the present embodiment includes the piezoelectric vibrators 1 electrically connected to a filter section 131. The radio-controlled timepiece 130 is a clock with a function of receiving a standard radio wave including the clock information, automatically changing it to the correct time, and displaying the correct time.

In Japan, there are transmission centers (transmission stations) that transmit a standard radio wave in Fukushima Prefecture (40 kHz) and Saga Prefecture (60 kHz), and each center transmits the standard radio wave. A long wave with a frequency of, for example, 40 kHz or 60 kHz has both a characteristic of propagating along the land surface and a characteristic of propagating while being reflected between the ionospheric layer and the land surface, and therefore has a propagation range wide enough to cover the entire area in Japan through the two transmission centers.

Hereinafter, the functional configuration of the radio-controlled timepiece 130 will be described in detail.

An antenna 132 receives a long standard radio wave with a frequency of 40 kHz or 60 kHz. The long standard radio wave is obtained by performing AM modulation of the time information, which is called a time code, using a carrier wave with a frequency of 40 kHz or 60 kHz. The received long standard wave is amplified by an amplifier 133 and is then filtered and synchronized by the filter section 131 having the plurality of piezoelectric vibrators 1.

In the present embodiment, the piezoelectric vibrators 1 include crystal vibrator sections 138 and 139 having resonance frequencies of 40 kHz and 60 kHz, respectively, which are the same frequencies as the carrier frequency.

In addition, the filtered signal with a predetermined frequency is detected and demodulated by a detection and rectification circuit 134. Then, the time code is extracted by a waveform shaping circuit 135 and counted by the CPU 136. The CPU 136 reads the information including the current year, the total number of days, the day of the week, the time, and the like. The read information is reflected on an RTC 137, and the correct time information is displayed.

Because the carrier wave is 40 kHz or 60 kHz, a vibrator having the tuning fork structure described above is suitable for the crystal vibrator sections 138 and 139.

Moreover, although the above explanation has been given for the case in Japan, the frequency of a long standard wave is different in other countries. For example, a standard wave of 77.5 kHz is used in Germany. Therefore, when the radio-controlled timepiece 130 which is also operable in other countries is assembled in a portable device, the piezoelectric vibrator 1 corresponding to frequencies different from the frequencies used in Japan is necessary.

As described above, since the radio-controlled timepiece 130 according to the present embodiment includes the high-quality piezoelectric vibrator 1 having improved yield in which reliable airtightness in the cavity C is secured, it is possible to achieve an improvement in the operational reliability and high quality of the radio-controlled timepiece itself which provides stable conductivity. In addition to this, it is possible to measure time highly accurately and stably over a long period of time.

While the embodiments of the invention have been described in detail with reference to the accompanying drawings, the specific configuration is not limited to the above-described embodiments, and various changes may be made in design without departing from the spirit of the invention.

For example, although in the above-described embodiment, the through-holes 30 and 31 have a conical shape having a tapered sectional shape, they may have an approximately circular columnar shape having a straight shape rather than the tapered sectional shape.

Moreover, the core portion 7 has been described as having a circular columnar shape, but it may have a rectangular columnar shape. In this case, the same operational effect can be obtained.

In addition, in the above-described embodiment, it is preferable that the core portion 7 has approximately the same thermal expansion coefficient as the base substrate 2 (base substrate wafer 40) and the cylindrical member 6.

In this case, when baking is performed, the three members, namely the base substrate wafer 40, the cylindrical member 6, and the core portion 7 will experience the same thermal expansion. Therefore, there will be no problems resulting from the different thermal expansion coefficients, for example, a case where excessive pressure is applied to the base substrate wafer 40 or the cylindrical member 6, thus forming cracks or the like, and a case where a gap is formed between the cylindrical member 6 and the through-holes 30 and 31 or between the cylindrical member 6 and the core portion 7. Therefore, it is possible to form the penetration electrodes having higher quality, and accordingly, to achieve a further improvement in the quality of the piezoelectric vibrator 1.

For example, although the above-described embodiments have been described by way of an example of the grooved piezoelectric vibrating reed 4 in which the groove portions 18 are formed on both surfaces of the vibrating arms 10 and 11 as an example of the piezoelectric vibrating reed 4, the piezoelectric vibrating reed 4 may be a type of piezoelectric vibrating reed without the groove portions 18. However, since the field efficiency between the pair of the excitation electrodes 15 when a predetermined voltage is applied to the pair of excitation electrodes 15 can be increased by forming the groove portions 18, it is possible to suppress the vibration loss further and to improve the vibration properties much more. That is to say, it is possible to decrease the CI value (crystal impedance) further and to improve the performance of the piezoelectric vibrating reed 4 further. In this respect, it is preferable to form the groove portions 18.

In addition, although the embodiment has been described by way of an example of a tuning-fork type piezoelectric vibrating reed 4, the piezoelectric vibrating reed of the present invention is not limited to the tuning-fork type piezoelectric vibrating reed but may be a thickness-shear type piezoelectric vibrating reed, for example.

Moreover, although in the above-described embodiments, the base substrate 2 and the lid substrate 3 are anodically bonded by the bonding film 35, the bonding method is not limited to the anodic bonding. However, anodic bonding is preferable because the anodic bonding can tightly bond both substrates 2 and 3.

Furthermore, although in the above-described embodiments, the piezoelectric vibrating reed 4 is bonded by bumps, the bonding method is not limited to bump bonding. For example, the piezoelectric vibrating reed 4 may be bonded by a conductive adhesive agent. However, since the bump bonding allows the piezoelectric vibrating reed 4 to be floated from the upper surface of the base substrate 2, it is naturally possible to secure the minimum vibration gap necessary for vibration of the piezoelectric vibrating reed 4. Therefore, bump bonding is preferable.

In the above-described embodiment, although the length of the core portion 7 has been described as being set to a length shorter by a distance of 0.02 mm than the thickness of the base substrate wafer 40, the length can be freely set as long as the squeegee 45 does not make contact with the core portion 7 when the redundant glass paste 6a is removed by the squeegee 45.

In addition, in the present embodiment, the rivet member 9 in which the tip end of the core portion 7 has a flat surface before the polishing step was used, but the tip end may not be a flat surface, and the length of the core portion 7 may be shorter than the thickness of the base substrate wafer 40 when the rivet members 9 are disposed in the through-holes 30 and 31.

In the above-described embodiment, although the lead-out electrodes 36 and 37 were formed by the mask sputtering method, the respective electrodes of the piezoelectric vibrating reed 4, the outer electrodes, and the like may be formed by the mask sputtering method using a masking material having approximately the same configuration as described above.

What is claimed is:

1. A device for spattering patterns on a wafer, comprising a mask being defined with a plurality of areas in each of which pattern holes are formed and having a thickness substantially uniform across the mask.

2. The device according to claim 1, wherein the mask is made of magnetic material.

3. The device according to claim 2, wherein the mask is made of stainless steel.

4. The device according to claim 1, further comprising a base plate having a loop of ridge elevated to form a recess for receiving the wafer.

5. The device according to claim 4, wherein the ridge has a height substantially equal to a thickness of the wafer.

6. The device according to claim 4, wherein the mask is large enough to be placed on the ridge.

7. The device according to claim 4, wherein the mask is shaped substantially similarly to the base plate.

8. The device according to claim 1, further comprising a magnet plate to magnetically secure the mask in place.

9. A device for spattering patterns on a wafer, comprising a mask being defined with a plurality of areas in each of which a recess is formed with pattern holes being formed in a bottom of the recess, the mask having a thickness substantially uniform across the wafer except the recesses.

10. The device according to claim 9, wherein the mask is formed in two layers each having a thickness substantially uniform across the mask.

11. A method for producing piezoelectric vibrators, comprising:
(a) defining a plurality of first substrates on a first wafer and a plurality of second substrates on a second wafer;
(b) forming patters on the first wafer by spattering, using a mask being defined with a plurality of areas substantially coincident with at least some of the first substrates, each area having pattern holes formed therein, and the mask having a thickness substantially uniform across the mask;
(c) layering the first and second wafers such that at least some of the first substrates substantially coincide respectively with at least some of the corresponding second substrates, wherein a piezoelectric vibrating strip is secured in a respective at least some of coinciding first and second substrates;
(d) cutting off a respective at least some of packages made of coinciding first and second substrates.

12. The method according to claim 11, wherein the mask is made of magnetic material.

13. The method according to claim 12, wherein the mask is made of stainless steel.
